(19) United States
(12) Patent Application Publication
(10) Pub. No.: US 2024/0276110 A1
(43) Pub. Date: Aug. 15, 2024

(54) INFORMATION PROCESSING DEVICE

(71) Applicant: SONY SEMICONDUCTOR SOLUTIONS CORPORATION, Kanagawa (JP)

(72) Inventors: Shinichi MIYAKE, Kanagawa (JP); Katsuhiko HANZAWA, Kanagawa (JP); Kazuyuki TOMIDA, Kanagawa (JP)

(73) Assignee: SONY SEMICONDUCTOR SOLUTIONS CORPORATION, Kanagawa (JP)

(21) Appl. No.: 18/684,287

(22) PCT Filed: Mar. 7, 2022
(86) PCT No.: PCT/JP2022/009607

§ 371 Date: Feb. 16, 2024

(30) Foreign Application Priority Data
Aug. 24, 2021 (JP) 2021-136439

(51) Int. Cl. H04N 25/47

(52) U.S. Cl. CPC H04N 25/47

(57) ABSTRACT

The present technology relates to an information processing device capable of detecting an event with higher accuracy. The information processing device includes a plurality of detection pixels that generates a voltage signal in accordance with a logarithmic value of a photocurrent, and a detection circuit that detects whether or not a change amount of the voltage signal of a detection pixel indicated by an input selection signal among the plurality of detection pixels exceeds a predetermined threshold value, in which a gate of a transistor included in the detection circuit includes a plurality of metal layers and a High-K layer. The High-K layer is polarized. The present technology can be applied to, for example, an information processing device that detects an address event for each pixel.

### TECHNICAL FIELD

The present technology relates to an information processing device, and for example, relates to an information processing device capable of detecting an event with higher accuracy.

### BACKGROUND ART

A synchronous imaging element that captures image data (frame) in synchronization with a synchronization signal such as a vertical synchronization signal is used in a known imaging device or the like. Such a general synchronous imaging element can acquire image data only for each period (for example, 1/60 seconds) of the synchronization signal, and it is therefore difficult to handle a case where faster processing is required in the fields related to traffic, robots, or the like. Thus, there has been proposed an asynchronous imaging element that detects, for each pixel address, the fact that the change amount of luminance of a corresponding pixel has exceeded a threshold value as an address event (see, for example, Patent Document 1). Such an imaging element that detects an address event for each pixel is called an event-based vision sensor (EVS).

### CITATION LIST

### Patent Document

Patent Document 1: WO 2019/087471

### SUMMARY OF THE INVENTION

### Problems to be Solved by the Invention

The above-described asynchronous imaging element detects the presence or absence of the address event to increase throughput of processing such as image recognition. In order to detect the presence or absence of the address event, it is, however, necessary to arrange a large number of circuits such as a logarithmic response unit, a buffer, a differentiator, and a comparator for each pixel, and the circuit scale of each pixel tends to increase as compared with a synchronous imaging element.

Such circuits include a plurality of transistors, and if transistors with suitable characteristics are not arranged, there is a possibility that performance deteriorates or an increase in throughput is hindered. It is desirable to employ a configuration where transistors having suitable characteristics are arranged.

The present technology has been made in view of such circumstances, and it is therefore an object of the present technology to provide a transistor having a suitable characteristic.

### Solutions to Problems

A first information processing device according to one aspect of the present technology is an information processing device including a plurality of detection pixels that generates a voltage signal in accordance with a logarithmic value of a photocurrent, and a detection circuit that detects whether or not a change amount of the voltage signal of a detection pixel indicated by an input selection signal among the plurality of detection pixels exceeds a predetermined threshold value, in which a gate of a transistor included in the detection circuit includes a plurality of metal layers and a High-K layer.

A second information processing device according to one aspect of the present technology is an information processing device including a plurality of detection pixels that generates a voltage signal in accordance with a logarithmic value of a photocurrent, and a detection circuit that detects whether or not a change amount of the voltage signal of a detection pixel indicated by an input selection signal among the plurality of detection pixels exceeds a predetermined threshold value, in which a transistor included in the detection circuit includes a negative capacitance field effect transistor (NCFET).

A third information processing device according to one aspect of the present technology is an information processing device including a plurality of detection pixels that generates a voltage signal in accordance with a logarithmic value of a photocurrent, and a detection circuit that detects whether or not a change amount of the voltage signal of a detection pixel indicated by an input selection signal among the plurality of detection pixels exceeds a predetermined threshold value, in which a transistor included in the detection circuit includes a fully-depleted silicon on insulator (FD-SOI)-type transistor.

A fourth information processing device according to one aspect of the present technology is an information processing device including a plurality of detection pixels that generates a voltage signal in accordance with a logarithmic value of a photocurrent, and a detection circuit that detects whether or not a change amount of the voltage signal of a detection pixel indicated by an input selection signal among the plurality of detection pixels exceeds a predetermined threshold value, in which a transistor included in the detection circuit includes a tunnel field effect transistor (TFET).

In the first information processing device according to one aspect of the present technology, the plurality of detection pixels that generates the voltage signal in accordance with the logarithmic value of the photocurrent, and the detection circuit that detects whether or not the change amount of the voltage signal of a detection pixel indicated by the input selection signal among the plurality of detection pixels exceeds a predetermined threshold value are included, and the gate of the transistor included in the detection circuit includes the plurality of metal layers and the High-K layer.

In the second information processing device according to one aspect of the present technology, the plurality of detection pixels that generates the voltage signal in accordance with the logarithmic value of the photocurrent, and the detection circuit that detects whether or not the change amount of the voltage signal of a detection pixel indicated by the input selection signal among the plurality of detection pixels exceeds the predetermined threshold value are included, and the transistor included in the detection circuit includes the negative capacitance field effect transistor (NCFET).

In the third information processing device according to one aspect of the present technology, the plurality of detection pixels that generates the voltage signal in accordance with the logarithmic value of the photocurrent, and the detection circuit that detects whether or not the change amount of the voltage signal of a detection pixel indicated by the input selection signal among the plurality of detection pixels exceeds the predetermined threshold value are included, and the transistor included in the detection circuit includes the fully-depleted silicon on insulator (FD-SOI)-type transistor.

In the fourth information processing device according to one aspect of the present technology, the plurality of detection pixels that generates the voltage signal in accordance with the logarithmic value of the photocurrent, and the detection circuit that detects whether or not the change amount of the voltage signal of a detection pixel indicated by the input selection signal among the plurality of detection pixels exceeds the predetermined threshold value are included, and the transistor included in the detection circuit includes the tunnel field effect transistor (TFET).

Note that the information processing device may be an independent device or an internal block constituting one device.

### BRIEF DESCRIPTION OF DRAWINGS

FIG. 1 is a block diagram depicting a configuration of an embodiment of an EVS camera to which the present technology is applied.

FIG. 2 is a block diagram depicting a schematic configuration example of an imaging element.

FIG. 3 is a block diagram depicting a configuration example of an address event detection circuit.

FIG. 4 is a circuit diagram depicting a detailed configuration of a current-voltage conversion circuit, a subtractor, and a quantizer.

FIG. 5 is a diagram depicting a more detailed circuit configuration example of the address event detection circuit.

FIG. 6 is a circuit diagram depicting another configuration example of the quantizer.

FIG. 7 is a diagram depicting a more detailed circuit configuration example of the address event detection circuit in a case where the quantizer is adopted.

FIG. 8 is a diagram depicting a configuration example of a transistor according to a first embodiment.

FIG. 9 is a diagram for describing a metal gate and an HK layer.

FIG. 10 is a diagram for describing polarization.

FIG. 11 is a diagram depicting a configuration example of a transistor according to a second embodiment.

FIG. 12 is a diagram depicting a configuration example of a transistor according to a third embodiment.

FIG. 13 is a diagram depicting a configuration example of a transistor according to a fourth embodiment.

FIG. 14 is a diagram depicting a configuration example of a transistor according to a fifth embodiment.

FIG. 15 is a diagram depicting a configuration example of a transistor according to a sixth embodiment.

FIG. 16 is a diagram depicting a configuration example of a transistor according to a seventh embodiment.

FIG. 17 is a diagram depicting a configuration example of a transistor according to an eighth embodiment.

FIG. 18 is a diagram depicting a configuration example of a transistor according to a ninth embodiment.

FIG. 19 is a diagram depicting a configuration example of a transistor according to a tenth embodiment.

FIG. 20 is a block diagram depicting an example of schematic configuration of a vehicle control system.

FIG. 21 is a diagram of assistance in explaining an example of installation positions of an outside-vehicle information detecting section and an imaging section.

### MODE FOR CARRYING OUT THE INVENTION

Hereinafter, modes for carrying out the present technology (hereinafter referred to as embodiments) will be described.

### <Configuration Example of EVS Camera>

An EVS camera 10 is a camera including an event sensor that outputs, as event data, a temporal change of an electrical signal obtained by photoelectrically converting an optical signal. Such an event sensor is also referred to as an event-based vision sensor (EVS). While a camera including a general image sensor captures an image in synchronization with a vertical synchronization signal, and outputs frame data that is image data of one frame (screen) in the period of the vertical synchronization signal, the EVS camera 10 outputs event data only at a timing when an event occurs, so that it can be said that the EVS camera 10 is an asynchronous or address control camera.

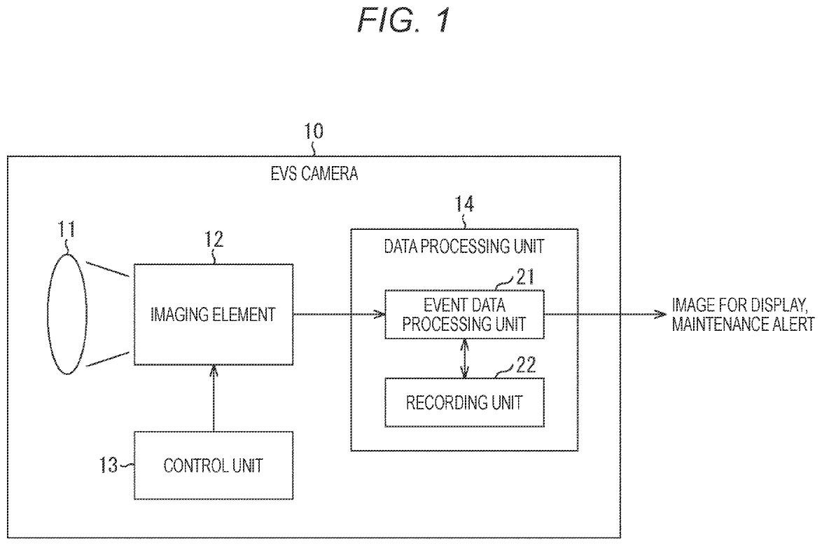

The EVS camera 10 depicted in FIG. 1 includes an optical unit 11, an imaging element 12, a control unit 13, and a data processing unit 14.

The optical unit 11 collects light from a subject and causes the light to enter the imaging element 12. The imaging element 12 photoelectrically converts incident light incident via the optical unit 11 to generate event data, and supplies the event data to the data processing unit 14. The imaging element 12 is a light receiving element that outputs event data indicating an occurrence of an event with a luminance change in a pixel as the event.

The control unit 13 controls the imaging element 12. For example, the control unit 13 instructs the imaging element 12 to start and end imaging.

The data processing unit 14 includes, for example, a field programmable gate array (FPGA), a digital signal processor (DSP), or a microprocessor, and performs predetermined processing. The data processing unit 14 includes an event data processing unit 21 and a recording unit 22. For example, the event data processing unit 21 performs event data processing using event data supplied from the imaging element 12, and image data processing using an event image. The recording unit 22 records and accumulates, as necessary, predetermined data in a predetermined recording medium.

### <Configuration Example of Imaging Element>

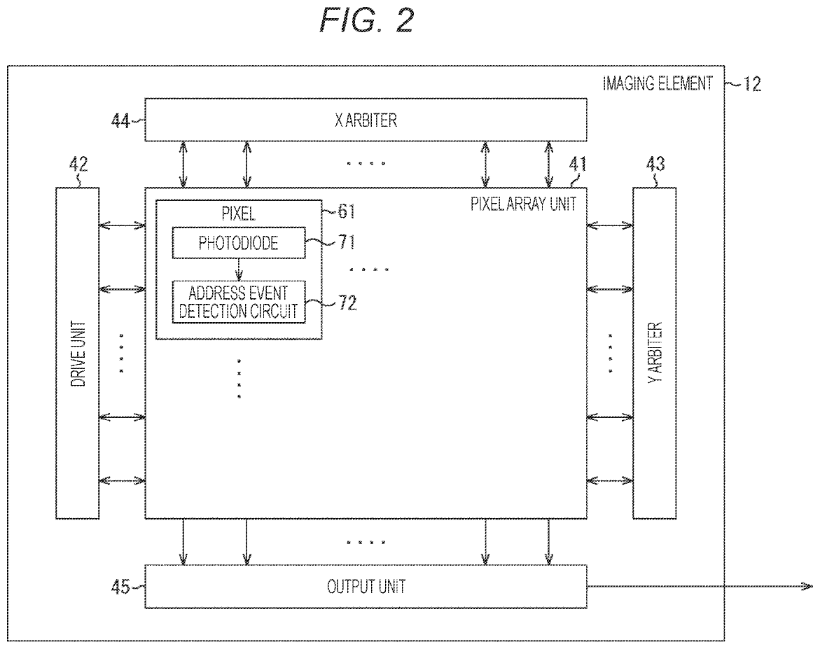

FIG. 2 is a block diagram depicting a schematic configuration example of the imaging element 12. The imaging element 12 includes a pixel array unit 41, a drive unit 42, a Y arbiter 43, an X arbiter 44, and an output unit 45.

In the pixel array unit 41, a plurality of pixels 61 is arranged in a two-dimensional lattice manner. Each pixel 61 includes a photodiode 71 as a photoelectric conversion element and an address event detection circuit 72. In a case where a change exceeding a predetermined threshold value occurs in a photocurrent as an electrical signal generated by photoelectric conversion of the photodiode 71, the address event detection circuit 72 detects the change in the photocurrent as an event. In a case where an event is detected, the address event detection circuit 72 outputs a request requesting output of event data indicating the occurrence of the event to the Y arbiter 43 and the X arbiter 44.

The drive unit 42 drives the pixel array unit 41 by supplying a control signal to each pixel 61 of the pixel array unit 41.

The Y arbiter 43 arbitrates requests from the pixels 61 in the same row in the pixel array unit 41, and returns a response indicating permission or non-permission of output of event data to the pixel 61 that has transmitted the request. The X arbiter 44 arbitrates requests from the pixels 61 in the same column in the pixel array unit 41, and returns a response indicating permission or non-permission of output of event data to the pixel 61 that has transmitted the request. A pixel 61 to which a permission response has been returned from both the Y arbiter 43 and the X arbiter 44 can output event data to the output unit 45.

Note that the imaging element 12 may include only one of the Y arbiter 43 or the X arbiter 44. For example, in a case where only the X arbiter 44 is included, data of all the pixels 61 in the same column including the pixel 61 that has transmitted the request is transferred to the output unit 45. Then, in the output unit 45 or the data processing unit 14 (FIG. 1) in the subsequent stage, only event data of a pixel 61 where an event has actually occurred is selected. In a case where only the Y arbiter 43 is included, pixel data is transferred to the output unit 45 in units of rows, and only event data of a necessary pixel 61 is selected in the subsequent stage.

The output unit 45 performs necessary processing on the event data output from each pixel 61 constituting the pixel array unit 41, and supplies the processed event data to the data processing unit 14 (FIG. 1).

### <Configuration Example of Address Event Detection Circuit>

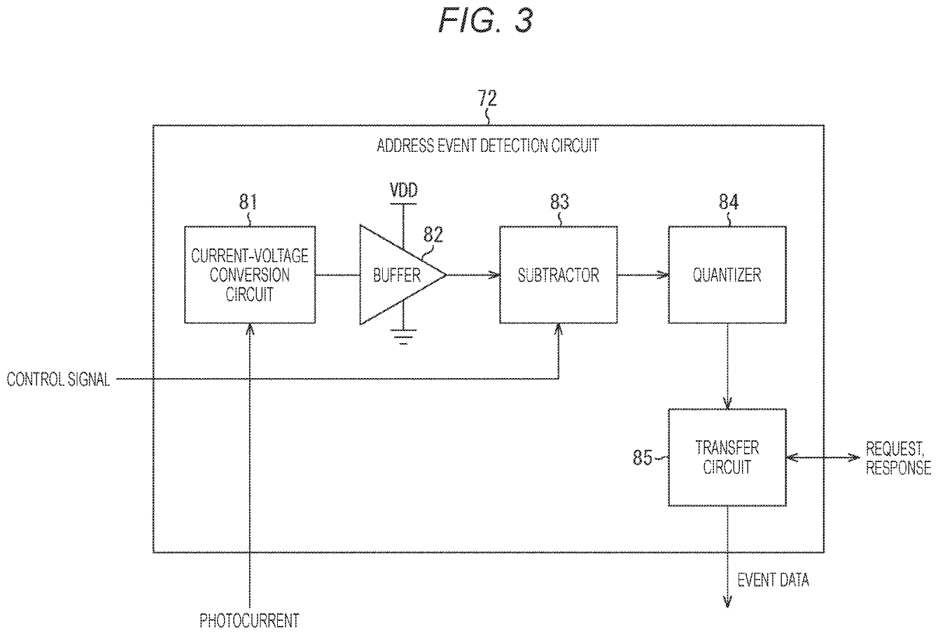

FIG. 3 is a block diagram depicting a configuration example of the address event detection circuit 72. The address event detection circuit 72 includes a current-voltage conversion circuit 81, a buffer 82, a subtractor 83, a quantizer 84, and a transfer circuit 85. The current-voltage conversion circuit 81 converts a photocurrent from the corresponding photodiode 71 into a voltage signal. The current-voltage conversion circuit 81 generates a voltage signal corresponding to a logarithmic value of the photocurrent, and outputs the voltage signal to the buffer 82.

The buffer 82 buffers the voltage signal from the current-voltage conversion circuit 81, and outputs the voltage signal to the subtractor 83. This buffer 82 makes it possible to secure isolation of noise accompanying a switching operation in a subsequent stage, and to improve a driving force for driving the subsequent stage. Note that the buffer 82 can be omitted.

The subtractor 83 lowers a level of the voltage signal from the buffer 82, in accordance with a control signal from the drive unit 42. The subtractor 83 outputs the lowered voltage signal to the quantizer 84.

The quantizer 84 quantizes the voltage signal from the subtractor 83 into a digital signal, and supplies the digital signal to the transfer circuit 85 as event data. The transfer circuit 85 transfers (outputs) the event data to the output unit 45. That is, the transfer circuit 85 supplies a request requesting output of the event data to the Y arbiter 43 and the X arbiter 44. In a case where a response indicating that output of the event data is permitted is received from the Y arbiter 43 and the X arbiter 44 in response to the request, the transfer circuit 85 transfers the event data to the output unit 45.

### <Detailed Configuration Example of Address Event Detection Circuit>

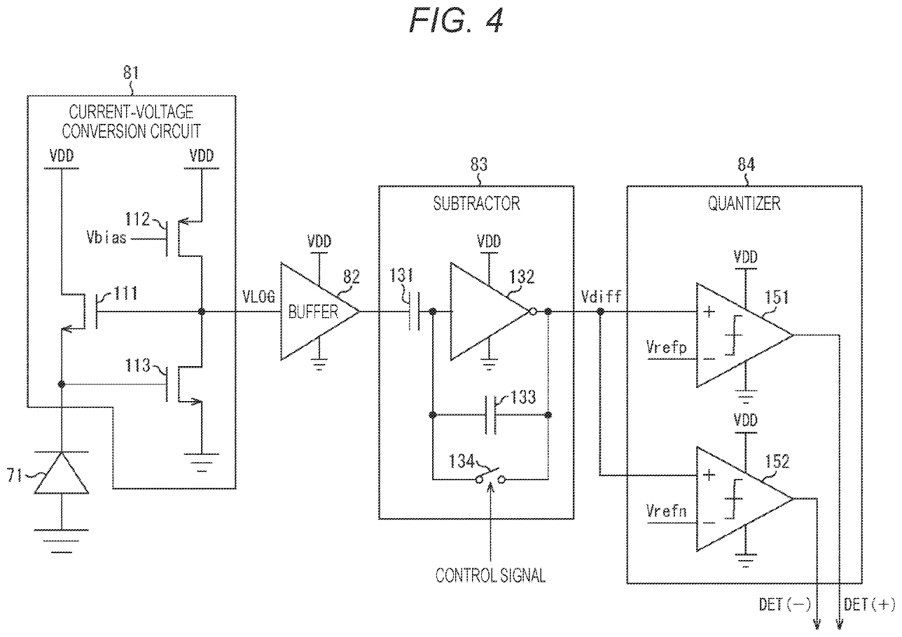

FIG. 4 is a circuit depicting a detailed configuration of the current-voltage conversion circuit 81, the subtractor 83, and the quantizer 84. In FIG. 4, the photodiode 71 connected to the current-voltage conversion circuit 81 is also depicted.

The current-voltage conversion circuit 81 includes FETs 111 to 113. As the FETs 111 and 113, for example, an N-type metal oxide semiconductor (NMOS) FET can be adopted, and as the FET 112, for example, a P-type metal oxide semiconductor (PMOS) FET can be adopted.

The photodiode 71 receives incident light, performs photoelectric conversion, and generates and allows flowing of a photocurrent as an electrical signal. The current-voltage conversion circuit 81 converts the photocurrent from the photodiode 71 into a voltage (hereinafter, also referred to as a photovoltage) VLOG corresponding to a logarithm of the photocurrent, and outputs the voltage VLOG to the buffer 82.

A source of the FET 111 is connected to a gate of the FET 113, and a photocurrent from the photodiode 71 flows through a connection point between the source of the FET 111 and the gate of the FET 113. A drain of the FET 111 is connected to a power supply VDD, and a gate thereof is connected to a drain of the FET 113.

A source of the FET 112 is connected to the power supply VDD, and a drain thereof is connected to a connection point between the gate of the FET 111 and the drain of the FET 113. A predetermined bias voltage Vbias is applied to a gate of the FET 112. A source of the FET 113 is grounded.

The drain of the FET 111 is connected to the power supply VDD side, and is a source follower. The photodiode 71 is connected to the source of the FET 111 that is a source follower, and this connection allows flowing of a photocurrent due to an electric charge generated by photoelectric conversion of the photodiode 71, through (the drain to the source of) the FET 111. The FET 111 operates in a subthreshold region, and the photovoltage VLOG corresponding to a logarithm of the photocurrent flowing through the FET 111 appears at the gate of the FET 111. As described above, in the photodiode 71, the photocurrent from the photodiode 71 is converted into the photovoltage VLOG corresponding to the logarithm of the photocurrent by the FET 111.

The photovoltage VLOG is outputted from the connection point between the gate of the FET 111 and the drain of the FET 113 to the subtractor 83 via the buffer 82.

For the photovoltage VLOG from the current-voltage conversion circuit 81, the subtractor 83 computes a difference between a photovoltage at the present time and a photovoltage at a timing different from the present time by a minute time, and outputs a difference signal Vdiff corresponding to the difference.

The subtractor 83 includes a capacitor 131, an operational amplifier 132, a capacitor 133, and a switch 134. The quantizer 184 includes comparators 151 and 152.

One end of the capacitor 131 is connected to an output of the buffer 82, and another end is connected to an input terminal of the operational amplifier 132. Therefore, the photovoltage VLOG is input to the (inverting) input terminal of the operational amplifier 132 via the capacitor 131.

An output terminal of the operational amplifier 132 is connected to non-inverting input terminals (+) of the comparators 151 and 152 of the quantizer 184.

One end of the capacitor 133 is connected to the input terminal of the operational amplifier 132, and another end is connected to the output terminal of the operational amplifier 132.

The switch 134 is connected to the capacitor 133 so as to turn on/off connection between both ends of the capacitor 133. The switch 134 turns on/off the connection between both ends of the capacitor 133 by turning on/off in accordance with a control signal of the drive unit 142.

The capacitor 133 and the switch 134 constitute a switched capacitor. When the switch 134 having been turned off is temporarily turned on and turned off again, the capacitor 133 is reset to a state in which electric charges are discharged and electric charges can be newly accumulated.

The photovoltage VLOG of the capacitor 131 on the photodiode 71 side when the switch 134 is turned on is denoted by Vinit, and a capacitance (an electrostatic capacitance) of the capacitor 131 is denoted by C1. The input terminal of the operational amplifier 132 is virtually grounded, and an electric charge Qinit accumulated in the capacitor 131 in a case where the switch 134 is turned on is expressed by Formula (1).

$$Qinit = C 1 \times Vinit \qquad ( 1 )$$

Furthermore, in a case where the switch 134 is on, both ends of the capacitor 133 are short-circuited, so that the electric charge accumulated in the capacitor 133 becomes 0.

Thereafter, when the photovoltage VLOG of the capacitor 131 on the photodiode 71 side in a case where the switch 134 is turned off is denoted by Vafter, an electric charge Qafter accumulated in the capacitor 131 when the switch 134 is turned off is represented by Formula (2).

$$Qafter = C 1 \times Vafter \qquad ( 2 )$$

When the capacitance of the capacitor 133 is denoted by C2, then an electric charge Q2 accumulated in the capacitor 133 is represented by Formula (3) by using the difference signal Vdiff which is an output voltage of the operational amplifier 132.

$$Q 2 = - C 2 \times Vdiff \qquad ( 3 )$$

Before and after the switch 134 is turned off, a total electric charge amount of the electric charge of the capacitor 131 and the electric charge of the capacitor 133 does not change, so that Formula (4) is established.

$$Qinit = Qafter + Q 2 \qquad ( 4 )$$

When Formulas (1) to (3) are substituted into Formula (4), Formula (5) is obtained.

$$Vdiff = - ( C 1 / C 2 ) \times ( Vafter - Vinit ) \qquad ( 5 )$$

According to Formula (5), the subtractor 83 subtracts the photovoltages Vafter and Vinit, that is, calculates the difference signal Vdiff corresponding to a difference (Vafter−Vinit) between the photovoltages Vafter and Vinit. According to Formula (5), a gain of subtraction by the subtractor 183 is C1/C2. Therefore, the subtractor 183 outputs, as the difference signal Vdiff, a voltage obtained by multiplying a change in the photovoltage VLOG after resetting of the capacitor 133 by C1/C2.

The subtractor 183 outputs the difference signal Vdiff by turning on and off the switch 134 with a control signal outputted from the drive unit 142.

The difference signal Vdiff output from the subtractor 183 is supplied to the non-inverting input terminals (+) of the comparators 151 and 152 of the quantizer 184.

The comparator 151 compares the difference signal Vdiff from the subtractor 183 with a positive-side threshold value Vrefp input to an inverting input terminal (−). The comparator 151 outputs a detection signal DET(+) of a high (H) level or a low (L) level indicating whether or not the difference signal Vdiff has exceeded the positive-side threshold value Vrefp to the transfer circuit 185 as a quantized value of the difference signal Vdiff.

The comparator 152 compares the difference signal Vdiff from the subtractor 183 with a negative-side threshold value Vrefn input to an inverting input terminal (−). The comparator 152 outputs a detection signal DET(−) of a high (H) level or a low (L) level indicating whether or not the difference signal Vdiff has exceeded the negative-side threshold value Vrefn to the transfer circuit 185 as a quantized value of the difference signal Vdiff.

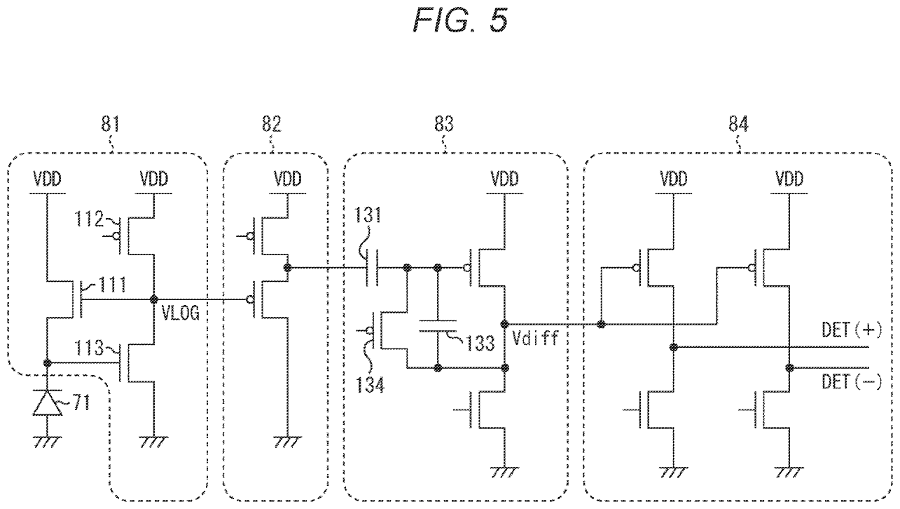

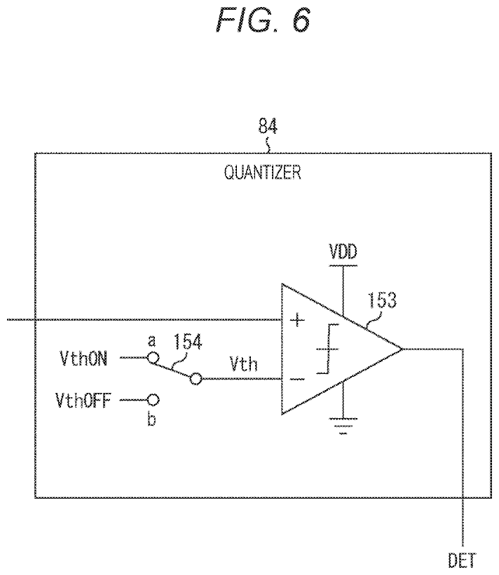

FIG. 5 depicts a more detailed circuit configuration example of the current-voltage conversion circuit 81, the buffer 82, the subtractor 83, and the quantizer 84 depicted in FIG. 4. FIG. 6 is a circuit diagram depicting another configuration example of the quantizer 84.

The quantizer 84 depicted in FIG. 5 constantly compares the difference signal Vdiff from the subtractor 83 with both the positive-side threshold value (voltage) Vrefp and the negative-side threshold value (voltage) Vrefn, and outputs a comparison result.

On the other hand, the quantizer 84 in FIG. 6 includes one comparator 153 and a switch 154, and outputs a comparison result of comparison with any one of two threshold values (voltages) VthON and VthOFF switched by the switch 154.

The switch 154 is connected to an inverting input terminal (−) of the comparator 153, and selects a terminal a or b in accordance with a control signal from the drive unit 142. The voltage VthON as a threshold value is supplied to the terminal a, and the voltage VthOFF (<VthON) as a threshold value is supplied to the terminal b. Therefore, the voltage VthON or VthOFF is supplied to the inverting input terminal of the comparator 153.

The comparator 153 compares the difference signal Vdiff from the subtractor 83 with the voltage VthON or VthOFF, and outputs a detection signal DET of an H-level or an L-level indicating a result of the comparison to the transfer circuit 85 as a quantized value of the difference signal Vdiff.

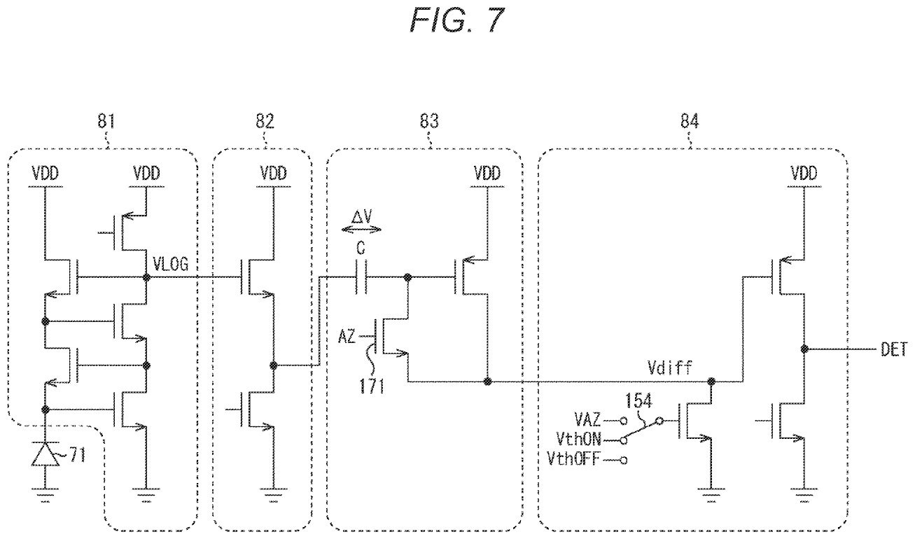

FIG. 7 depicts a more detailed circuit configuration example of the current-voltage conversion circuit 81, the buffer 82, the subtractor 83, and the quantizer 84 in a case where the quantizer 84 depicted in FIG. 6 is adopted.

In the circuit configuration of FIG. 7, a terminal VAZ for initialization (AutoZero) is also added as a terminal of the switch 154 in addition to the voltage VthON and the voltage VthOFF. At a timing when an H (High) level initialization signal AZ is supplied to a gate of an FET 171 that is an N-type MOS (NMOS) FET in the subtractor 83, the switch 154 of the quantizer 84 selects the terminal VAZ and executes an initialization operation. Thereafter, the switch 154 selects the terminal of the voltage VthON or the terminal of the voltage VthOFF on the basis of a control signal from the drive unit 42, and a detection signal DET indicating a result of comparison with the selected threshold value is output from the quantizer 84 to the transfer circuit 85.

### <Performance Required for Transistor>

As described above, the EVS camera 10 converts a photocurrent into a logarithmic voltage and determines that an event has occurred when the change amount exceeds a certain threshold value. Since it is important for the event whether or not to exceed the threshold value, the linearity of a holding node is only required to be in a range (both positive and negative) of the reset up to the threshold value, and when falling out of the range, it is determined as an event, so that the linearity may be somewhat poor, in other words, even if there is a leak, it can be considered that the linearity is in an allowable range.

On the other hand, in order to obtain the change amount, the EVS camera 10 first performs a reset operation (hereinafter, described as an AZ operation as appropriate) on an amplifier. It is necessary for the AZ operation to make output and input identical in voltage to each other, so that a low resistance is required (a low threshold value Vt is required). On the other hand, it is necessary to hold a reference voltage until a change occurs (to be exact, a holding voltage continues to change with time and is held until the threshold value is exceeded), so that low leakage characteristics are required (high threshold value). As described above, required performance differs between ON and OFF.

In the EVS camera 10, logarithmic transformation is performed before the subtractor. An input amplitude is compressed, an event threshold value is set close to a reset voltage. One of the characteristics of the linearity required for the holding portion of the EVS camera 10 is that the linearity is in a range of the reset up to the threshold value, and the range is narrower than the full swing (power supply GND). Therefore, a low threshold value can be adopted.

In order to make the threshold value more flexible, a switch transistor preferably has a high OFF resistance. Therefore, a transistor having a suitable S value is used as the switch transistor.

As a transistor related to the AZ operation of the EVS camera 10, it is preferable to use a device having the threshold value Vt as low as about 0 V and a suitable S value. The lower the threshold value, the more suitable the S value, and the threshold value can be set as low as about 0 V. The use of such a transistor allows a reduction in ON resistance while suppressing leakage.

A description will be given below with the FET 171 including the NMOS FET included in the subtractor 83 taken as an example of a transistor having a low threshold value Vt and a low S value. The description will be continued with the FET 171 denoted as an AZ transistor 171.

Note that, here, the description will be continued with the AZ transistor 171 taken as an example, but the technology described below may also be applied to other transistors included in the EVS camera 10. Note that, here, the description will be continued with a transistor having a low threshold value Vt and a suitable S value taken as an example; however, according to the present technology, an adjustment such as setting the threshold value lower or higher can be performed, and an adjustment such as setting the S value lower or higher can also be performed, so that the application range of the present technology is not limited to the transistor having a low threshold value of 0 V and a low S value.

### <Configuration of Transistor According to First Embodiment>

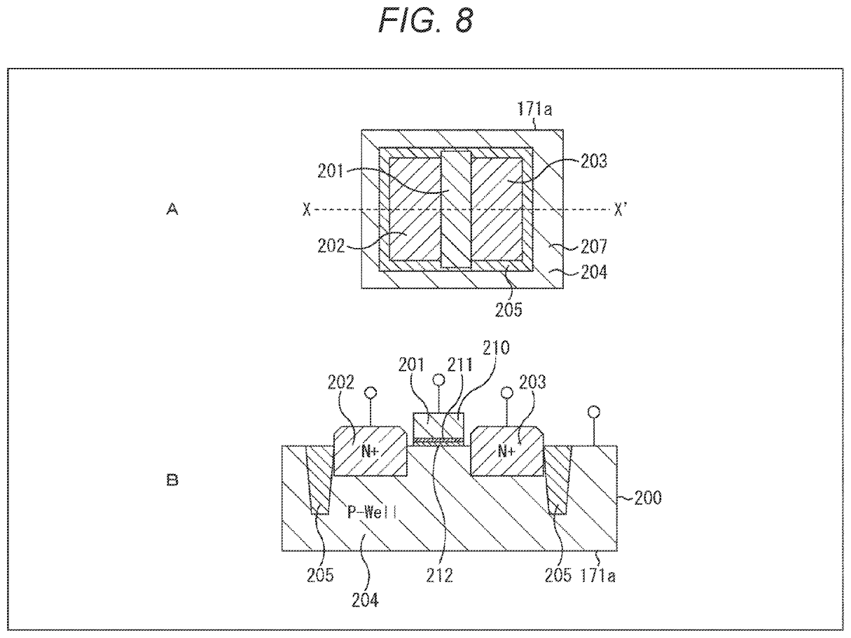

FIG. 8 is a diagram depicting a configuration example of an AZ transistor 171a according to a first embodiment. A of FIG. 8 is a plan view of the AZ transistor 171a. B of FIG. 8 is a cross-sectional view of the AZ transistor 171a depicted in A of FIG. 8, taken along a line X-X′ as viewed from above.

A gate 201 is formed near the center of the AZ transistor 171a, an N+-type source 202 is formed on the left side, and an n+-type drain 203 is formed on the right side. The AZ transistor 171a is formed in a P-WELL region 204. The gate 201, the source 202, and the drain 203 are surrounded by shallow trench isolation (STI) 205 and are separated from each other.

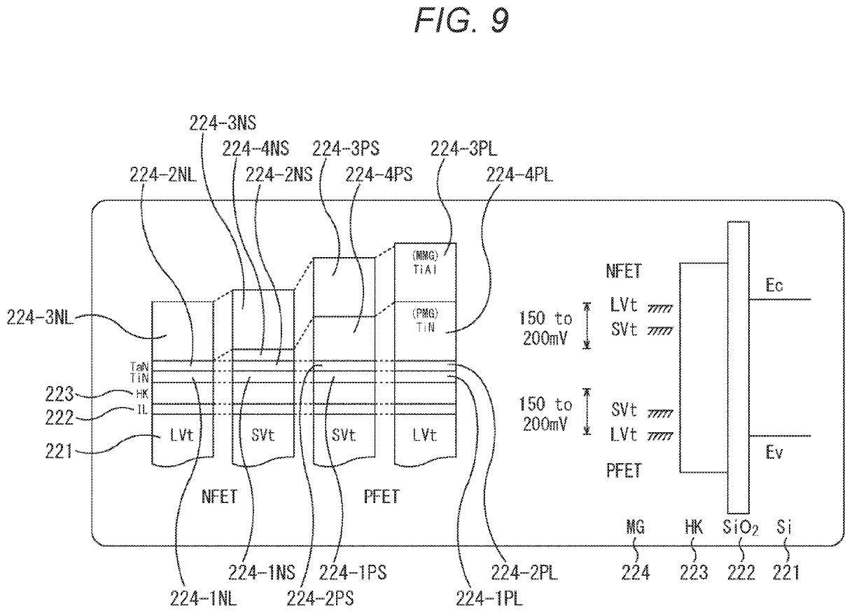

The gate 201 includes a metal gate and a High-K (hereinafter, denoted as HK). The gate 201 includes a metal gate 210, an HK layer 211, and an insulating layer 212 stacked together. The configuration of the gate 201 will be described with reference to FIG. 9.

FIG. 10 is a diagram for describing the configuration of the gate 201. The gate 201 includes a silicon substrate 221, an insulating layer (interfacial Layer: IL) 222 stacked on the silicon substrate 221, a High-K (HK) layer 223 stacked on the insulating layer 222, and a metal layer 224 stacked on the HK layer 223. The insulating layer 222, the HK layer 223, and the metal layer 224 depicted in FIG. 10 correspond to the insulating layer 212, the HK layer 211, and the metal gate 210 depicted in FIG. 9, respectively.

The insulating layer 222 includes a material having insulating properties such as silicon dioxide (SiO2). The HK layer 223 includes a material higher in relative permittivity than silicon dioxide, and for example, hafnium oxide (HfO2), hafnium silicate (HfSiO4), or the like can be used as the material. An insulating layer functioning as an insulating layer is formed by the insulating layer 222 and the HK layer 223.

The metal layer 224 includes a plurality of metals stacked together, and serves as a layer capable of controlling a work function. In the example depicted in FIG. 9, in a case where the n-channel field effect transistor (NFET) is configured to be on a low threshold voltage (LVt) side, the metal layer 224 includes a tin (TiN) layer 224-1NL, a tantalum nitride (TaN) layer 224-2NL, and a titanium aluminum (TiAl) layer 224-3NL.

In the example depicted in FIG. 9, in a case where an n-channel field effect transistor (NFET) is configured to be on a standard threshold voltage (SVt) side, the metal layer 224 includes a TiN layer 224-INS, a TaN layer 224-2NS, a TaN layer 224-4NS, and a TiAl layer 224-3NS.

Even for the gate of the NFET, the material and thickness of the metal included in the metal layer 224 are different between the case where the NFET is configured to be on the low threshold voltage (LVt) side and the case where the NFET is configured to be on the standard threshold voltage (SVt) side. In the example depicted in FIG. 9, the gate 201 configured to be on the standard threshold voltage (SVt) side has a configuration where the TaN layer 224-4NS is added to the gate 201 configured to be on the low threshold voltage (LVt) side.

In the example depicted in FIG. 9, in a case where a p-channel field effect transistor (PFET) is configured to be on the standard threshold voltage (SVt) side, the metal layer 224 includes a TiN layer 224-1PS, a TaN layer 224-2PS, a TaN layer 224-4PS, and a TiAl layer 224-3PS.

In the example depicted in FIG. 9, in a case where the p-channel field effect transistor (PFET) is configured to be on the low threshold voltage (LVt) side, the metal layer 224 includes a TiN layer 224-1PL, a TaN layer 224-2PL, a TaN layer 224-4PL, and a TiAl layer 224-3PL.

In the case of the gate of the PFET, the material and stacking order of the metal included in the metal layer 224 are the same between the case where the PFET is configured to be on the low threshold voltage (LVt) side and the case where the PFET is configured to be on the standard threshold voltage (SVt) side, but the thickness is different. In the example depicted in FIG. 9, in a case where the gate 201 configured to be on the standard threshold voltage (SVt) side and the gate 201 configured to be the low threshold voltage (LVt) side are compared, the TaN layer 224-4PL is thicker than the TaN layer 224-4PS.

In a case where the gate 201 of the NFET configured to be on the standard threshold voltage (SVt) side and the gate 201 of the PFET configured to be on the standard threshold voltage (SVt) side are compared, the TaN layer 224-4PS is thicker than the TaN layer 224-4NS.

In the metal layer 224, the threshold value Vt can be controlled by not only causing the TiN layer 224-1, the TaN layer 224-2, or the like to function as a High-K Cap layer, but also using a work function of the metal. For example, in a device for lowering the threshold value with the NFET depicted in FIG. 9 (the diagram depicted on the left side in FIG. 9), the TiAl layer 224-3 containing Al having a work function close to the conduction band (Ec) is provided on the High-k cap layer.

On the other hand, it is possible to increase the threshold value Vt of the NFET by providing a thin TiN layer 224-4 serving as a P metal gate on the High-k cap layer. Furthermore, it is possible to make the threshold value suitable for the PFET by increasing the film thickness of the TiN layer 224-4PL and controlling the work function toward the Valence band (Ev).

As described above, it is possible to configure the gate 201 close to a desired voltage by changing the type and thickness of the metal included in the metal layer 224. The configuration of the gate 201 described with reference to FIG. 9 is an example, and is not construed as a limitation. A type and a thickness of metal according to performance required for a transistor can be used.

When the gate 201 includes a combination of a metal gate and a High-K, it is possible to lower the threshold value Vt (make threshold value Vt lower). Furthermore, the threshold value Vt is made lower without impurity introduction such as counter doping, which prevents the S value from degrading, so that a transistor having characteristics required for the AZ transistor 171a can be provided.

Note that, as described above, since it is possible to configure a gate close to a desired voltage by changing the type and thickness of the metal included in the metal layer 224, it is also possible to form, for example, a device having a high Vt and a suitable S value other than a device having a low threshold value Vt and a suitable S value.

In a case where the HK layer 223 is provided, the HK layer 223 has a dipole formed therein, which also allows a further reduction in threshold value Vt. As depicted in FIG. 10, the HK layer 223 is mixed with, for example, lanthanum (La) 231. As described above, it is also possible to lower the threshold value of the NFET by introducing atoms such as lanthanum (La) different in Fermi level from hafnium (Hf).

Although not depicted, a case where aluminum is introduced into the HK layer 223 can make the polarity opposite to the case where lanthanum is introduced. That is, it is possible to control the polarity direction using the atoms introduced into the HK layer 223, so that a desired polarity can be obtained.

As described above, with the configuration where the dipole is formed in the HK layer 223, the threshold value Vt may be adjusted.

In the AZ transistor 171a according to the first embodiment, for example, the threshold value Vt can be set within a range of about 0 to 0.2 v, and the S value can be set within a range of about 60 to 90 mv/dec.

### <Configuration of Transistor According to Second Embodiment>

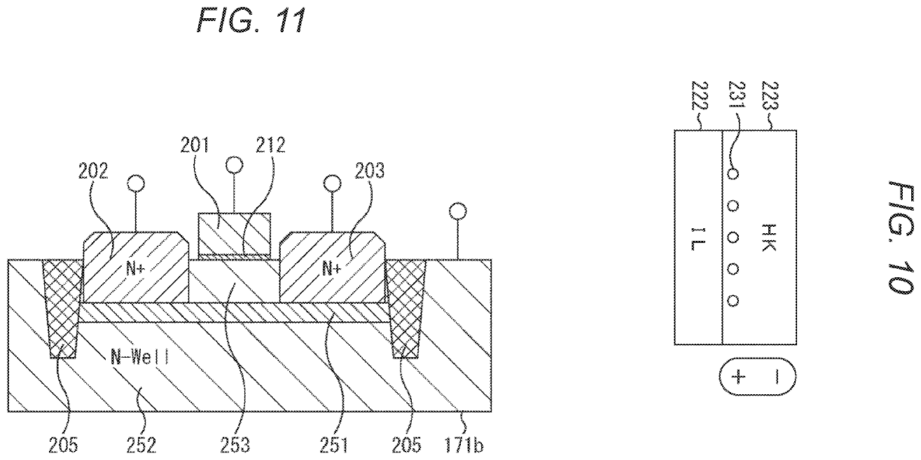

FIG. 11 is a diagram depicting a configuration example of an AZ transistor 171b according to a second embodiment. The AZ transistor 171b according to the second embodiment is similar in configuration as viewed from above to the AZ transistor 171a depicted in A of FIG. 8, so that the configuration is not depicted in the drawing. The AZ transistor 171b depicted in FIG. 11 corresponds to a diagram depicting a cross-sectional configuration example taken along the line X-X′ in A of FIG. 8.

The AZ transistor 171b depicted in FIG. 11 is a transistor having a configuration called a fully-depleted silicon on insulator (FD-SOI) or the like. A gate 201 of the FD-SOI-type AZ transistor 171b is formed on an insulating layer 212 provided on an SOI substrate. A non-doped region 253 is provided under the insulating layer 212 and between a source 202 and a drain 203.

In the FD-SOI-type AZ transistor 171b, a buried oxide layer (hereinafter, referred to as a BOX layer 251) is formed as an extremely thin layer (of, for example, 10 to 300 nm) on the SOI substrate.

The FD-SOI-type AZ transistor 171b can reduce, with the BOX layer 251, a parasitic capacitance value between the source 202 and the drain 203. Electrons flowing from the source 202 to the drain 203 can be efficiently controlled, and a current leakage can be significantly reduced. That is, the threshold value Vt can be made lower, and the S value can be made more suitable.

In the AZ transistor 171b depicted in FIG. 11, a layer under the BOX layer 251 is an N-Well layer 252. In a case where the source 202 and the drain 203 are each an NMOS including N-type, the NMOS is in the SOI substrate, and a layer under the BOX layer 251 is an N-type WELL layer. A configuration where a forward bias is applied to the N-Well layer 252 may be employed.

In a case where a forward bias is applied to the NMOS, a positive (+) bias is applied to the N-Well layer 252. The voltage of the forward bias may be fixed (bias is continuously applied) or variable (bias is applied as necessary). In a case where the voltage is variable, a dynamic adjustment can be made while the AZ transistor 171b is in operation. With the configuration where a forward bias is applied to the N-Well layer 252, it is possible to further lower the threshold value Vt and make the S value more suitable.

It is possible to obtain the AZ transistor 171b having a more desired threshold value Vt and S value by causing the source 202 and the drain 203 formed on the BOX layer 251 and the WELL layer in which the BOX layer 251 is formed to have the same polarity, that is, an N pole in a case of the example depicted in FIG. 11, and employing the configuration where a forward bias is applied to the N-Well layer 252.

Note that, here, the description has been given with NMOS taken as an example, but the configuration can also be applied to PMOS. The configuration can be applied only by changing the polarity in the case of NMOS to the polarity in the case of PMOS. For example, the N-Well region 252 is used in the case of NMOS, but a P-WELL region may be used in the case of PMOS. The following description will be continued with the case of NMOS taken as an example, but the configuration can also be applied to PMOS.

A configuration may be employed where the AZ transistor 171a according to the first embodiment is applied to the AZ transistor 171b according to the second embodiment to configure the gate 201 as a gate including the metal gate 210, the HK layer 211, and the insulating layer 212.

### <Configuration of Transistor According to Third Embodiment>

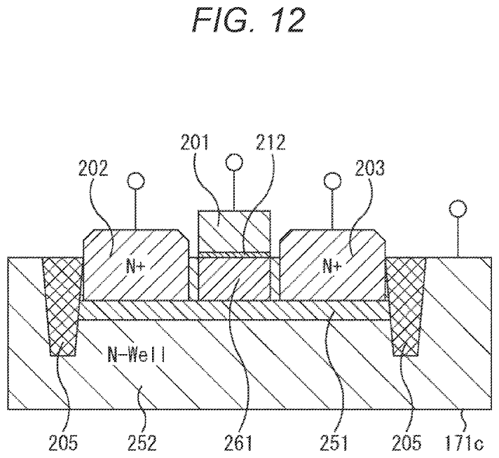

FIG. 12 is a diagram depicting a configuration example of an AZ transistor 171c according to a third embodiment. The AZ transistor 171c according to the third embodiment is similar in configuration as viewed from above to the AZ transistor 171a depicted in A of FIG. 8, so that the configuration is not depicted in the drawing. The AZ transistor 171c depicted in FIG. 12 corresponds to a diagram depicting a cross-sectional configuration example taken along the line X-X′in A of FIG. 8.

The AZ transistor 171c according to the third embodiment depicted in FIG. 12 is different from the AZ transistor 171b according to the second embodiment depicted in FIG. 11 in that a channel region 261 between the source 202 and the drain 203 is formed as a region counter-doped with impurities identical in polarity to the source 202 and the drain 203, and the other points are similar.

In the example depicted in FIG. 12, the source 202 and the drain 203 are N-type regions, so that the channel region 261 is also configured as an N-type region counter-doped with N-type impurities. As described above, with the configuration where the source 202, the drain 203, and the channel region 261 are identical in polarity to each other, it is possible to form a transistor that allows a further reduction in the threshold value Vt and has a suitable S value.

Note that in a case where it is desired to increase the threshold value Vt, the increase can be achieved by making the channel region 261 different in polarity from the source 202 and the drain 203. For example, in a case where the source 202 and the drain 203 are N-type regions, the channel region 261 is configured as a P-type region counter-doped with P-type impurities, so that the threshold value Vt can be increased.

As described above, it is possible to adjust the threshold value Vt by counter-doping the channel region 261 with impurities. It is also possible to adjust the threshold value Vt by adjusting the amount of impurities with which counter-doping is performed and obtain a transistor having more desired characteristics.

### <Configuration of Transistor According to Fourth Embodiment>

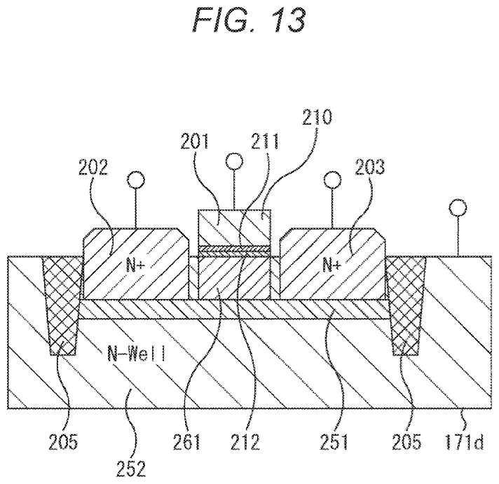

FIG. 13 is a diagram depicting a configuration example of an AZ transistor 171d according to a fourth embodiment. The AZ transistor 171d according to the fourth embodiment is similar in configuration as viewed from above to the AZ transistor 171a depicted in A of FIG. 8, so that the configuration is not depicted in the drawing. The AZ transistor 171d depicted in FIG. 13 corresponds to a diagram depicting a cross-sectional configuration example taken along the line X-X′ in A of FIG. 8.

The AZ transistor 171d according to the fourth embodiment depicted in FIG. 13 has a configuration obtained by combining the first to third embodiments. A gate 201 of the AZ transistor 171d depicted in FIG. 13 has a structure with the metal gate 210, the HK layer 211, and the insulating layer 212 stacked together.

The AZ transistor 171d depicted in FIG. 13 is an FD-SOI-type transistor, and has a configuration where a forward bias is applied to the N-Well layer 252. The AZ transistor 171d depicted in FIG. 13 has a configuration where the channel region 261 is counter-doped with N-type impurities.

With this configuration, it is possible to obtain the AZ transistor 171d having a more desired threshold value Vt, in this case, a low threshold value vt and a suitable S value.

### <Configuration of Transistor According to Fifth Embodiment>

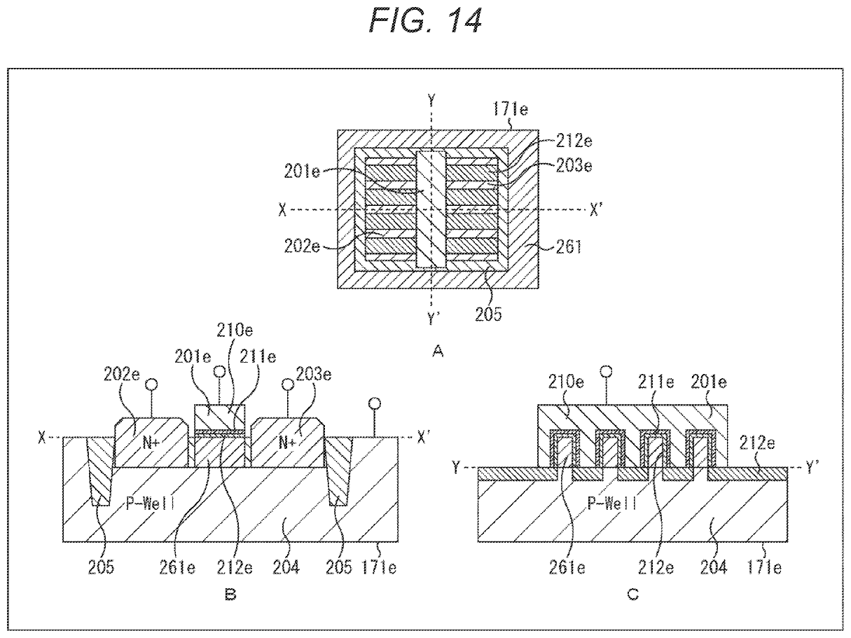

FIG. 14 is a diagram depicting a configuration example of an AZ transistor 171e according to a fifth embodiment. The AZ transistor 171e depicted in B of FIG. 14 indicates a cross-sectional configuration example of the AZ transistor 171e depicted in A of FIG. 14 taken along a line X-X′ as viewed from above, and the AZ transistor 171e depicted in C of FIG. 14 indicates a cross-sectional configuration example taken along a line Y-Y′ in A of FIG. 14.

The AZ transistor 171e according to the fifth embodiment is different from the AZ transistors 171 according to the first to fourth embodiments in that a configuration where a FinFET is applied is employed. The FinFET is an example of a multi-gate transistor, and is a field effect transistor (FET) having a fin-shaped (standing) silicon channel formed between a source and a drain and a gate electrode formed to cover the silicon channel.

With reference to A of FIG. 14, a source 202e and a drain 203e of the FinFET-type AZ transistor 171e are each formed in a fin shape, and as viewed from above, the source 202e and an insulating layer 212e are alternately arranged, and the drain 203e and the insulating layer 212e are alternately arranged. A channel region 261e is formed in a part of a gate 201e, in other words, a part between the source 202e and the drain 203e and included in the gate 201e as viewed from above.

With reference to B of FIG. 14, in the cross-sectional configuration example including the gate 201e, the source 202e, and the drain 203e, the AZ transistor 171e includes the gate 201 having a metal gate 210e, an HK layer 211e, and the insulating layer 212e stacked together, as with the AZ transistor 171a according to the first embodiment depicted in FIG. 8.

As with the AZ transistor 171d depicted in FIG. 13, the AZ transistor 171e has the channel region 261e counter-doped with N-type impurities. Note that, here, the description has been given with the case where the channel region 261e is a counter-doped region taken as an example, but the channel region may be a non-doped region. In a case where the channel region 261e is a region with low impurities, for example, it is possible to be set to 1e18/cm3 or less.

With reference to C of FIG. 14, the channel region 261e is formed in a fin shape in a part of the gate 201e. Each of the fin-shaped channel regions 261e is covered with the insulating layer 212e. The insulating layer 212e is also formed in the P-WELL region 204 and between the channel regions 261e. The HK layer 211e is further stacked on the insulating layer 212e stacked on the channel region 261e.

Each channel region 261e in which the channel region 261e, the insulating layer 212e, and the HK layer 211e are stacked together is covered with the metal gate 210e.

As described above, the gate 201e includes the insulating layer 212e, the HK layer 211e, and the metal gate 210e stacked together as described with reference to FIG. 8 and the like. With such a configuration of the gate 201e, it is possible to lower the threshold value Vt and make the S value more suitable as with the above-described embodiments. It is possible to obtain a transistor having more desired characteristics by adjusting the material used for the metal gate 210e or the thickness of the metal gate 210e, in other words, by selecting the work function. The HK layer 211e may have a dipole formed therein.

The source 202e and the drain 203e are formed in a fin shape, and the channel region 261e formed between the source 202e and the drain 203e is also formed in a fin shape. The FinFET is characterized in that the gate 201e surrounds the channel region 261e from a plurality of directions, so that it is possible to increase a gate area and increase a channel current driving force.

The fin-shaped part is almost depleted by the gate 201e in three directions, so that it is possible to form a fully-depleted FinFET, and it is possible to lower the threshold value Vt and make the S value more suitable, as with the fully-depleted silicon-on-insulator (FD-SOI)-type AZ transistor 171b according to the second embodiment depicted in FIG. 11. It is also possible to produce an effect of reducing a current leakage. It is therefore possible to lower the threshold value Vt and make the S value more suitable.

With the channel region 261e formed in the counter-doped structure, it is possible to lower the threshold value Vt and make the S value more suitable as with the above-described embodiments.

As described above, with the AZ transistor 171d according to the fifth embodiment, it is also possible to lower the threshold value Vt and make the S value more suitable.

### <Configuration of Transistor According to Sixth Embodiment>

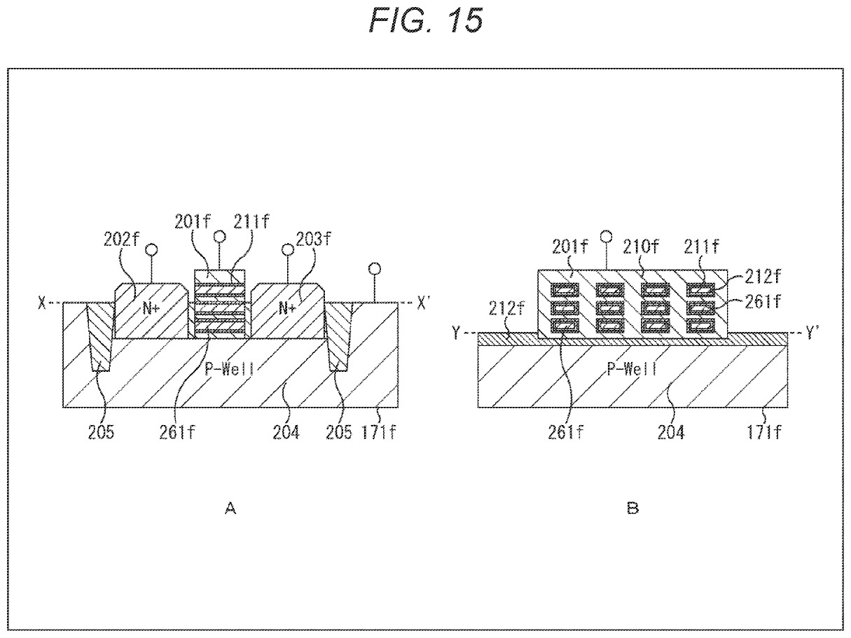

FIG. 15 is a diagram depicting a configuration example of an AZ transistor 171f according to the fifth embodiment. The AZ transistor 171f according to the sixth embodiment is similar in configuration as viewed from above to the AZ transistor 171e depicted in A of FIG. 14, so that the configuration is not depicted in the drawing. The AZ transistor 171f depicted in A of FIG. 15 indicates a cross-sectional configuration example of the AZ transistor 171e depicted in A of FIG. 14 taken along the line X-X′ as viewed from above, and the AZ transistor 171f depicted in B of FIG. 15 indicates a cross-sectional configuration example taken along the line Y-Y′ in A of FIG. 14.

The AZ transistor 171f according to the sixth embodiment is different from the AZ transistors 171 according to the first to fifth embodiments in that a configuration where a structure of a transistor called a gate all around FET (GAAFET), a Nano Wire FET, or the like is applied is employed.

In the GAAFET structure, a channel region 261f is formed in a gate 201f. With reference to B of FIG. 15, 12 channel regions 261f of 3×4 are formed in the gate 201f in the example depicted in B of FIG. 15. Each channel region 261f is surrounded by an insulating layer 212f, and the insulating layer 212f is surrounded by an HK layer 211f.

Although the rectangular channel region 261f is depicted in FIG. 15, the channel region 261f may have a circular shape or a polygonal shape in cross section. The insulating layer 212f and the HK layer 211f are also formed to match the shape of the channel region 261f.

The channel region 261f including the insulating layer 212f and the HK layer 211f stacked together is formed in a metal gate 210f. The gate 201f includes the metal gate 210f, the HK layer 211f, and the insulating layer 212f, and the plurality of channel regions 261f is included in the gate 201f.

With reference to A of FIG. 15, in the cross-sectional configuration example including the gate 201f, a source 202f, and a drain 203f, the gate 201f of the AZ transistor 171f includes the metal gate 210f, the HK layer 211f, the insulating layer 212f, and the channel region 261f stacked together.

As described above, the gate 201f includes the insulating layer 212f, the HK layer 211f, and the metal gate 210f stacked together, as with the configuration of the gate 201 described with reference to FIG. 8 and the like. With such a configuration of the gate 201f, it is possible to lower the threshold value Vt and make the S value more suitable as with the above-described embodiments. It is possible to obtain a transistor having more desired characteristics by adjusting the material used for the metal gate 210f and the thickness of the metal gate 210f, in other words, by selecting the work function. The HK layer 211f may have a dipole formed therein.

The channel region 261f is surrounded by the gate 201f from a plurality of directions, so that it is possible to increase the gate area and increase the channel current driving force. Compared with the AZ transistor 171e of the fifth embodiment, the channel region 261f has four surfaces surrounded by the gate 201f, so that it is possible to further increase the channel current driving force.

The channel region 261f is almost depleted by the gate 201f in the four directions, so that it is possible to form a fully-depleted GAAFET, and it is possible to reduce a current leakage, lower the threshold value Vt, and make the S value more suitable, as with the FD-SOI-type AZ transistor 171b according to the second embodiment depicted in FIG. 11.

With the channel region 261f formed in the counter-doped structure, it is possible to lower the threshold value Vt and make the S value more suitable as with the above-described embodiments.

As described above, with the AZ transistor 171d according to the sixth embodiment, it is also possible to lower the threshold value Vt and make the S value more suitable.

### <Configuration of Transistor According to Seventh Embodiment>

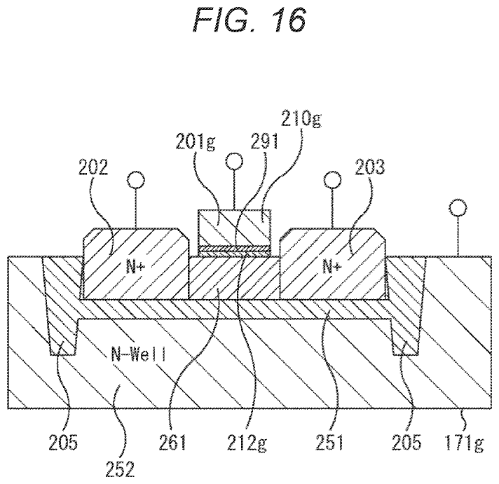

FIG. 16 is a diagram depicting a configuration example of an AZ transistor 171g according to a seventh embodiment. The AZ transistor 171g according to the seventh embodiment is similar in configuration as viewed from above to the AZ transistor 171a depicted in A of FIG. 8, so that the configuration is not depicted in the drawing. The AZ transistor 171g depicted in FIG. 16 indicates a cross-sectional configuration example of the AZ transistor 171a depicted in A of FIG. 8 taken along the line X-X′ as viewed from above.

The AZ transistor 171g according to the seventh embodiment is different from the AZ transistors 171 according to the first to sixth embodiments in that a configuration where a negative capacitance FET (NCFET) is applied is employed. The NCFET is a transistor obtained by replacing a gate insulating layer of a MOS transistor with a ferroelectric thin film and allows an increase in surface potential using a negative capacitance generated in a ferroelectric substance to make subthreshold characteristics steep.

The negative capacitance transistor (NCFET) using a dielectric substance as a gate insulating film is a transistor utilizing a phenomenon that when the capacitance of the gate insulating film becomes negative, the surface potential of the transistor is amplified. With this configuration, it is possible to make the subthreshold slope (S value) smaller than 60 mV/dec, which is the limit with a normal MOS transistor. It is therefore possible to lower the threshold value Vt and make the S value more suitable by applying the NCFET.

The AZ transistor 171g depicted in FIG. 16 indicates a configuration example where the NCFET structure is applied to the AZ transistor 171c according to the fourth embodiment depicted in FIG. 13. In the AZ transistor 171g to which the NCFET structure is applied, a gate 201g includes an insulating layer 212g, a ferroelectric layer 291, and a metal gate 210g stacked together. The insulating layer 212g may be an HK layer 211g formed by a High-K.

With the AZ transistor 171d according to the seventh embodiment, it is also possible to lower the threshold value Vt and make the S value more suitable.

### <Configuration of Transistor According to Eighth Embodiment>

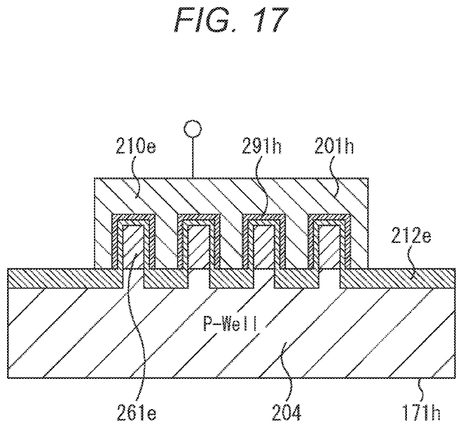

FIG. 17 is a diagram depicting a configuration example of an AZ transistor 171h according to an eighth embodiment. The AZ transistor 171h according to the eighth embodiment is similar in configuration as viewed from above to the AZ transistor 171e depicted in A of FIG. 14, so that the configuration is not depicted in the drawing. The AZ transistor 171h depicted in FIG. 17 indicates a cross-sectional configuration example of the AZ transistor 171e depicted in A of FIG. 14 taken along the line Y-Y′ as viewed from above.

The AZ transistor 171h according to the eighth embodiment depicted in FIG. 17 has a configuration where the NCFET structure is applied to the AZ transistor 171e according to the fifth embodiment depicted in FIG. 14. Portions similar to the portions of the AZ transistor 171e according to the fifth embodiment depicted in FIG. 14 are denoted by the same reference numerals, and the description of the portions will be omitted as appropriate.

The AZ transistor 171h depicted in FIG. 17 has a FinFET structure including the fin-shaped channel region 261e, and the channel region 261e has the NCFET structure with the insulating layer 212e and a ferroelectric layer 291h stacked together. The channel region 261e with the insulating layer 212e and the ferroelectric layer 291h stacked together is covered with the metal gate 210e constituting a gate 201h.

With the AZ transistor 171d according to the eighth embodiment, it is also possible to lower the threshold value Vt and make the S value more suitable.

### <Configuration of Transistor According to Ninth Embodiment>

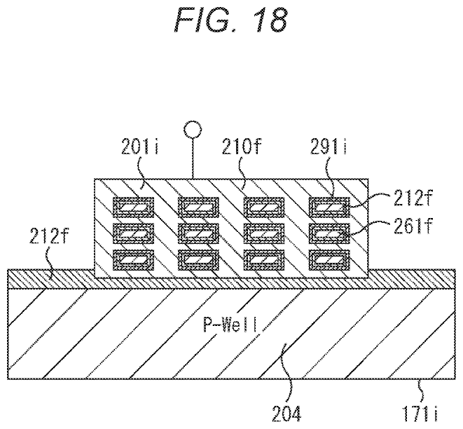

FIG. 18 is a diagram depicting a configuration example of an AZ transistor 171i according to a ninth embodiment. The AZ transistor 171i according to the ninth embodiment is similar in configuration as viewed from above to the AZ transistor 171e depicted in A of FIG. 14, so that the configuration is not depicted in the drawing. The AZ transistor 171i depicted in FIG. 18 indicates a cross-sectional configuration example of the AZ transistor 171e depicted in A of FIG. 14 taken along the line Y-Y′ as viewed from above.

The AZ transistor 171i according to the ninth embodiment depicted in FIG. 18 has a configuration where the NCFET structure is applied to the AZ transistor 171f according to the sixth embodiment depicted in FIG. 15. Portions similar to the portions of the AZ transistor 171f according to the sixth embodiment depicted in FIG. 15 are denoted by the same reference numerals, and the description of the portions will be omitted as appropriate.

The AZ transistor 171i depicted in FIG. 18 includes the channel region 261f having the gate all around FET structure, and the channel region 261f has the NCFET structure with the insulating layer 212f and a ferroelectric layer 291i stacked together. The channel region 261f with the insulating layer 212f and the ferroelectric layer 291i stacked together is covered with the metal gate 210f constituting a gate 201i.

With the AZ transistor 171i according to the ninth embodiment, it is also possible to lower the threshold value Vt and make the S value more suitable.

Note that the seventh to ninth embodiments indicate examples where the NCFET structure is applied to the fourth to sixth embodiments, but the NCFET structure can also be applied to the AZ transistors 171 according to the first to third embodiments.

### <Configuration of Transistor According to Tenth Embodiment>

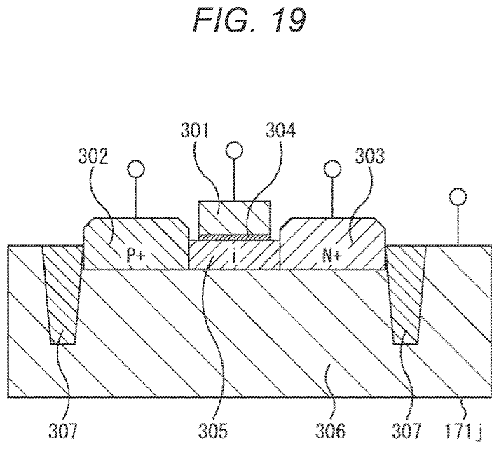

FIG. 19 is a diagram depicting a configuration example of an AZ transistor 171j according to a tenth embodiment. FIG. 19 depicts a cross-sectional configuration example of the AZ transistor 171j.

The AZ transistor 171j according to the tenth embodiment depicted in FIG. 19 is different from the AZ transistors 171 according to first to ninth embodiments in that the AZ transistor 171j has a tunnel FET (TFET) structure.

In the AZ transistor 171j, a source 302 of a P+-type semiconductor region is formed adjacent to the left side of a gate 301 in the drawing, and a drain 303 of an N+-type semiconductor region is formed adjacent to the right side in the drawing. The source 202 and the drain 203 of the above-described AZ transistor 171 such as the AZ transistor 171a depicted in

FIG. 8 are both formed as N-type semiconductor regions, whereas the source 302 and the drain 303 of the AZ transistor 171j are configured by semiconductor regions having different polarities.

An i-channel region 305 is formed between the source 302 and the drain 303. The i-channel region 305 is an intrinsic semiconductor region and is referred to as an i (intrinsic) type semiconductor or the like.

As a combination of materials of the P+-type source 302, the i-channel region 305, and the N+-type drain 303, a combination in which the P+-type source 302 includes P+-type GaAsSb, the i-channel region 305 includes i-type GaAs, and the N+-type drain 303 includes N+-type InGaAs can be applied. As another combination, a combination in which the P+-type source 302 includes Ge, Si, or the like, the i-channel region 305 includes MoS2 or the like, and the N+-type drain 303 includes Ge, Si, or the like can also be applied.

For the i-channel region 305, Si, a group III-V compound, a two-dimensional material (thin film substance having a two-dimensional atomic bonding structure), or the like can also be used.

The TFET has steep on/off characteristics as compared with the MOSFET, and can make the S value smaller than about 60 mV/dec. With the AZ transistor 171j according to the tenth embodiment, it is also possible to lower the threshold value Vt and make the S value more suitable.

In the above-described embodiments, the description has been given with the AZ transistor 171 taken as an example. The description has been given with the AZ transistor 171 taken as an example because it is preferable to use a transistor having a suitable S value in the vicinity of the low threshold value Vt (0 V); however, similarly, a transistor to which the present technology is applied can be used for a portion that requires a transistor having a suitable S value in the vicinity of the low threshold value Vt.

In the above-described embodiments, the description has been given with the transistor having a suitable S value in the vicinity of the low threshold value Vt taken as an example; however, it is possible to adjust the threshold value Vt and the S value by adjusting the material constituting the metal gate, the thickness of the metal gate, or the like to adjust the work function, adjusting the impurities with which the channel region is counter-doped or the impurity concentration, or applying any suitable structure of the first to tenth embodiments, and a transistor having a desired threshold value Vt and S value can be obtained. Therefore, the present technology can be applied to a transistor other than a transistor having a low threshold value Vt and a suitable S value. The present technology can also be applied to a device including such a transistor.

### <Example of Application to Mobile Body>

The technology according to the present disclosure (the present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, or a robot.

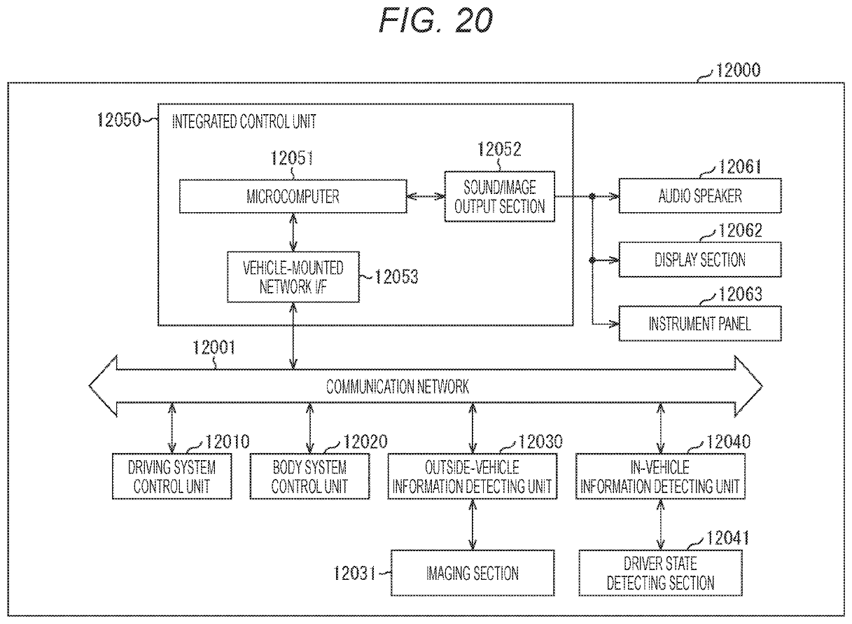

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are depicted as the output device. The display section 12062 may, for example, include at least one of an on-board display and a head-up display.

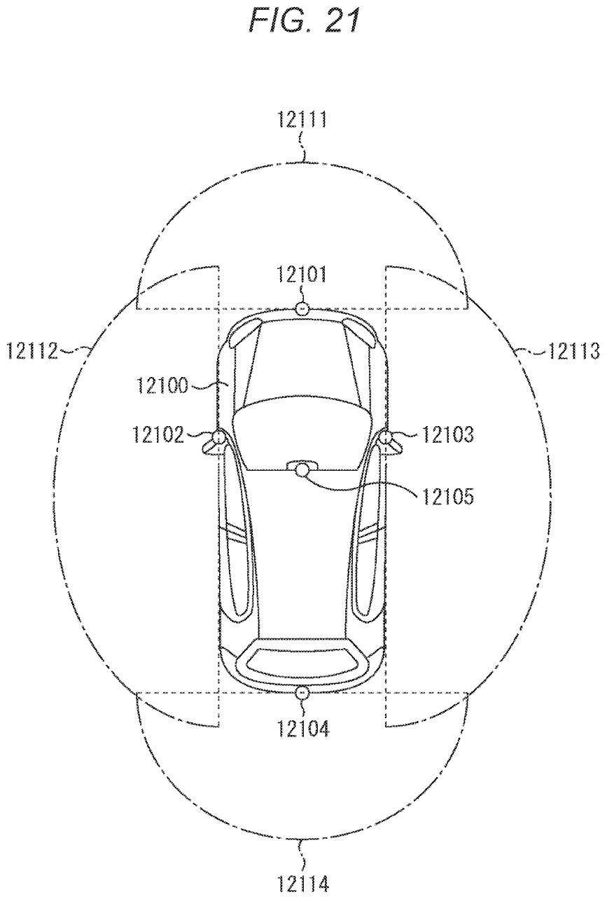

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire device including a plurality of devices.

Note that the effects described in the present specification are merely examples and are not restrictive, and there may be other effects.

Note that the embodiments of the present technology are not limited to the above-described embodiments, and various changes can be made without departing from the gist of the present technology.

Note that the present technology may also have the following configurations.

(1) An information processing device including:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, in which
a gate of a transistor included in the detection circuit includes a plurality of metal layers and a High-K layer.

(2) The information processing device according to (1), in which the High-K layer is polarized.

(3) The information processing device according to (1) or (2), in which the transistor includes a fully-depleted silicon on insulator (FD-SOI)-type transistor.

(4) The information processing device according to (3), in which a forward bias is applied to a well layer of the transistor.

(5) The information processing device according to (3), in which a channel region of the transistor includes a counter-doped region.

(6) The information processing device according to any one of (1) to (5), in which the transistor includes a Fin field effect transistor (FET).

(7) The information processing device according to any one of (1) to (5), in which the transistor includes a gate all around field effect transistor (GAA FET).

(8) The information processing device according to (6) or (7), in which a channel of the transistor includes a counter-doped region.

(9) The information processing device according to any one of (1) to (8), in which the transistor performs a process related to a reset operation.

(10) An information processing device including:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, in which
a transistor included in the detection circuit includes a negative capacitance field effect transistor (NCFET).

(11) The information processing device according to (10), in which the transistor includes a Fin field effect transistor (FET).

(12) The information processing device according to (10), in which the transistor includes a gate all around field effect transistor (GAA FET).

(13) An information processing device including:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, in which
a transistor included in the detection circuit includes a fully-depleted silicon on insulator (FD-SOI)-type transistor.

(14) The information processing device according to (13), in which a channel region of the transistor includes a counter-doped region.

(15) An information processing device including:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, in which
a transistor included in the detection circuit includes a tunnel field effect transistor (TFET).

### REFERENCE SIGNS LIST

10 EVS camera
11 Optical unit
12 Imaging element
13 Control unit
14 Data processing unit
21 Event data processing unit
22 Recording unit
41 Pixel array unit
42 Drive unit
43 Y arbiter
44 X arbiter
45 Output unit
61 Pixel
71 Photodiode
72 Address event detection circuit
81 Current-voltage conversion circuit
82 Buffer
83 Subtractor
84 Quantizer
85 Transfer circuit
131 Capacitor
132 Operational amplifier
133 Capacitor
134 Switch
142 Drive unit
151 Comparator
152 Comparator
153 Comparator
154 Switch
171 AZ transistor
183 Subtractor
184 Quantizer
185 Transfer circuit
201 Gate
202 Source
203 Drain
204 WELL region
210 Metal gate
211 HK layer
212 Insulating layer
221 Silicon substrate
222 Insulating layer
223 HK layer
224 Metal layer
251 BOX layer
252 Well layer
253 Region
261 Channel region
291 Ferroelectric layer
301 Gate
302 Source
303 Drain
305 i-channel region

What is claimed is:

1. An information processing device, comprising:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, wherein
a gate of a transistor included in the detection circuit includes a plurality of metal layers and a High-K layer.

2. The information processing device according to claim 1, wherein
the High-K layer is polarized.

3. The information processing device according to claim 1, wherein
the transistor includes a fully-depleted silicon on insulator (FD-SOI)-type transistor.

4. The information processing device according to claim 3, wherein
a forward bias is applied to a well layer of the transistor.

5. The information processing device according to claim 3, wherein
a channel region of the transistor includes a counter-doped region.

6. The information processing device according to claim 1, wherein
the transistor includes a Fin field effect transistor (FET).

7. The information processing device according to claim 1, wherein
the transistor includes a gate all around field effect transistor (GAA FET).

8. The information processing device according to claim 6, wherein
a channel of the transistor includes a counter-doped region.

9. The information processing device according to claim 1, wherein
the transistor performs a process related to a reset operation.

10. An information processing device, comprising:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, wherein
a transistor included in the detection circuit includes a negative capacitance field effect transistor (NCFET).

11. ) The information processing device according to claim 10, wherein
the transistor includes a Fin field effect transistor (FET).

12. The information processing device according to claim 10, wherein
the transistor includes a gate all around field effect transistor (GAA FET).

13. An information processing device, comprising:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, wherein
a transistor included in the detection circuit includes a fully-depleted silicon on insulator (FD-SOI)-type transistor.

14. The information processing device according to claim 13, wherein
a channel region of the transistor includes a counter-doped region.

15. An information processing device, comprising:
a plurality of detection pixels that generates a voltage signal in accordance with a logarithmic value of a photocurrent; and
a detection circuit that detects whether or not a change amount of the voltage signal of a detection pixel indicated by an input selection signal among the plurality of detection pixels exceeds a predetermined threshold value, wherein
a transistor included in the detection circuit includes a tunnel field effect transistor (TFET).
